(19) United States
(12) Patent Application Publication
(10) Pub. No.: US 2025/0329530 A1
(43) Pub. Date: Oct. 23, 2025

(54) DUAL PLASMA TREATMENT PROCESS

(71) Applicant: Applied Materials, Inc., Santa Clara, CA (US)

(72) Inventors: Jung chan LEE, San Jose, CA (US); Xiao LI, Santa Clara, CA (US); Praket Prakash JHA, San Jose, CA (US); Jingmei LIANG, San Jose, CA (US); Xiang JI, Sunnyvale, CA (US); Pavan Kumar CHINTHAMANIPETA SRIPADARAO, Santa Clara, CA (US)

(21) Appl. No.: 18/642,522

(22) Filed: Apr. 22, 2024

(51) Int. Cl. H01L 21/02; C23C 16/34; C23C 16/515; C23C 16/56

(52) U.S. Cl. CPC H01L 21/0234; C23C 16/345; C23C 16/515; C23C 16/56; H01L 21/0217

(57) ABSTRACT

Embodiments described herein generally relate to methods of post-treating a silicon-nitride (SiN)-based dielectric film formed on a surface of a substrate. The methods include positioning a substrate in a processing chamber. A dielectric precursor is supplied to the processing chamber. A plasma is provided to the processing chamber, in which the dielectric precursor reacts with a reactive gas in the plasma to form a silicon nitride (SiN)-based dielectric film on the substrate. A bias plasma is applied to the silicon nitride (SiN)-based dielectric film to form a condensed silicon nitride (SiN)-based dielectric film. The condensed dielectric film is cured

### BACKGROUND

### Field

Embodiments of the present disclosure generally relate to flowable gap-fill films and fabrication processes thereof, and more specifically, to post-treating flowable films by high-energy, low-dose plasma.

### Description of the Related Art

Fabrication of miniaturized semiconductor devices, including shallow trench isolation (STI), inter-metal dielectric (IMD) layers, inter-layer dielectric (ILD) layers, pre-metal dielectric (PMD) layers, passivation layers, fin-field-effective-transistors (FinFET), and the like, faces challenges in advanced lithography for patterning nano-scaled gate structures. Silicon nitride is one of primary dielectric materials used in such structures. Void-free filling of gaps and trenches has been performed by flowable chemical vapor deposition (CVD), in which silicon- and nitrogen-containing dielectric precursor in a liquid phase is delivered into gaps and trenches on a substrate (referred to as a flowable film), and then hardened into a silicon nitride (SiN)-based dielectric film in a solid phase, conventionally by steam annealing, ultraviolet (UV) irradiation, hot pressing, and sintering at high temperatures. However, such flowable films require elevated deposition temperatures, e.g., greater than 200° C., elevated cure temperatures, e.g., greater than 500° C., and have complex pattern loading controllability, e.g., bottom-up growth rate between narrow and wide opening critical dimensions. Moreover, such flowable films often include high wet etch rates, which can lead to downstream integration issues.

Therefore, a new process is needed to form flowable films that fill high aspect ratio gaps and trenches and have improved mechanical properties, such as an improved wet etch rate (WERR, <2:1), relative to silicon oxide.

### SUMMARY

Embodiments described herein generally relate to methods of post-treating a silicon-nitride (SiN)-based dielectric film formed on a surface of a substrate. The methods include positioning a substrate in a processing chamber. A dielectric precursor is supplied to the processing chamber. A plasma is provided to the processing chamber, in which the dielectric precursor reacts with a reactive gas in the plasma to form a silicon nitride (SiN)-based dielectric film on the substrate. A bias plasma is applied to the silicon nitride (SiN)-based dielectric film to form a condensed silicon nitride (SiN)-based dielectric film. The condensed dielectric film is cured.

Embodiments described herein also generally relate to methods of post-treating a silicon nitride (SiN)-based dielectric film formed on a surface of a substrate. A substrate is supplied to the processing chamber. A condensed silicon nitride (SiN)-based dielectric film is formed. A dielectric precursor is supplied to the processing chamber. A plasma is provided to the processing chamber, in which the dielectric precursor reacts with a reactive gas in the plasma to form a silicon nitride (SiN)-based dielectric film. A bias plasma is applied concurrently to form the condensed silicon nitride (SiN)-based dielectric film. The condensed silicon nitride (SiN)-based dielectric film is cured.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic view of a cluster tool, according to some embodiments of the present disclosure.

FIGS. 2A-2B are schematic views of a deposition chamber and showerhead, according to some embodiments of the present disclosure. FIG. 2A is a schematic view of a deposition chamber. FIG. 2B is a bottom view of a showerhead.

FIG. 3 is a schematic view of a plasma chamber, according to some embodiments of the present disclosure.

FIG. 4 is a flowchart showing a method of forming flowable films, according to some embodiments of the present disclosure.

FIGS. 5A-5D are diagrammatic representations of various treatment methods, according to some embodiments of the present disclosure.

FIGS. 6A-6E are diagrammatic representations of a flowable film filling a vertical trench, according to some embodiments of the present disclosure.

FIGS. 7A-7F are diagrammatic representations of a flowable film filling a horizontal trench, according to some embodiments of the present disclosure.

FIG. 8 is a graph showing electrical properties of a flowable film, according to some embodiments of the present disclosure.

FIG. 9 is a graph showing images of a reference flowable film and an example flowable film, according to some embodiments of the present disclosure.

FIG. 10 is a graph showing images of a reference flowable film, a first example flowable film, and a second example flowable film, according to some embodiments of the present disclosure.

For clarity, identical reference numerals have been used, where applicable, to designate identical elements that are common between figures. Additionally, elements of one embodiment may be advantageously adapted for utilization in other embodiments described herein.

### DETAILED DESCRIPTION

Embodiments described herein provide methods of depositing a low dielectric flowable film on a substrate, for example, by plasma flowable chemical vapor deposition (CVD). A silicon nitride (SiN)-based dielectric film contains silicon-nitrogen (Si—N—Si) bonds. A silicon nitride (SiN)-based dielectric film, as deposited on the substrate, may contain a large amount of silicon-hydrogen (Si—H) and nitrogen-hydrogen (N—H) bonds as a result of cross-linking of Si—H limited to near a surface of the deposited silicon nitrogen (Si—N)-based dielectric film, causing insufficient filling of gaps and trenches.

The present disclosure can provide a low temperature deposition process that enables uniform deposition and bottom up fill in narrow opening critical dimensions, reducing the formation of Si—H and/or N—H bonds. Moreover, the present disclosure can reduce the dielectric constant due to an increase in porosity and/or due to the formation of a non-polarization structure by providing SI—C based precursors with O, N incorporation. The techniques disclosed herein can improve the density of deposited films due to ion bombardment on the substrate support, thereby improving hardness and reducing dry/wet etch rate of the film. Additionally, the techniques disclosed herein provide a low thermal cure process, e.g., less than 500° C., thereby reducing Si—OH bonding and improving electrical properties, e.g., leakage current and/or breakdown voltage. Embodiments described herein also provide a tunable deposition process that can fill a gap of a structure, e.g., a vertical trench and/or a horizontal trench, in a gate all round transistor, e.g., 3D NAND, 3D DRAM and CFET device.

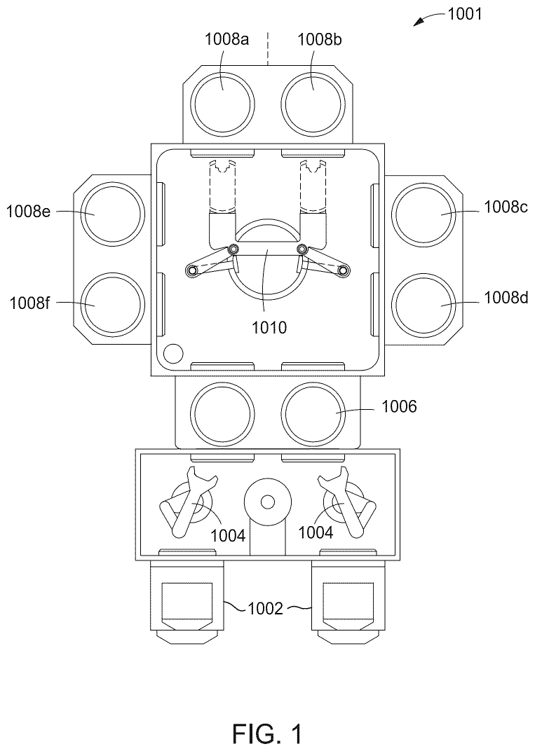

Embodiments of the deposition systems may be incorporated into larger fabrication systems for producing integrated circuit chips. FIG. 1 shows one such cluster tool 1001 that includes processing chambers 1008a-f, according to one embodiment. In FIG. 1, a pair of front opening unified pods (FOUPs) 1002 supply substrates (e.g., 300 mm diameter wafers) that are received by robotic arms 1004 and placed into a low pressure holding area 1006. A second robotic arm 1010 may be used to transport the substrate between the lower pressure holding area 1006 and the processing chambers 1008a-f.

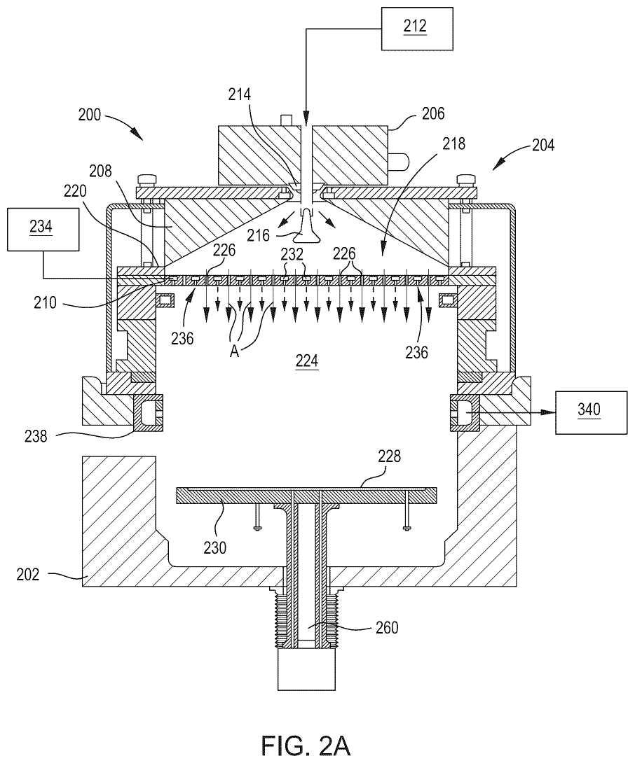

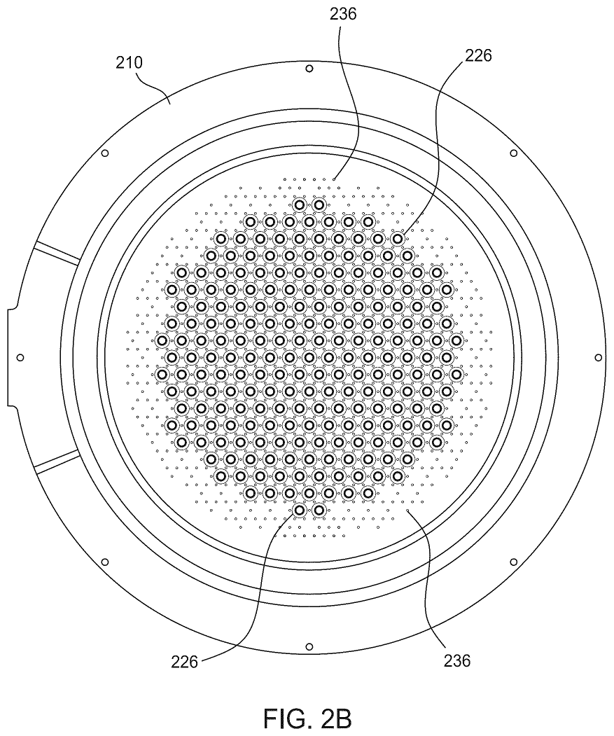

FIG. 2A is a schematic view of a processing chamber 200 having a chamber body 202 and lid assembly 204, according to one embodiment. The lid assembly 204 generally includes a remote plasma source (RPS) 206, a lid 208, and a dual channel showerhead (DCSH) 210. The RPS 206 may process a processing precursor gas provided from a processing precursor gas source 212. The plasma formed in the RPS 206 may be then delivered through a gas inlet assembly 214 and baffle 216, which are coupled to the lid 308, and into a chamber plasma region 218. A carrier gas (e.g., Ar, He) may be delivered into the chamber plasma region 218. The lid (that is a conductive top portion) 208 and the dual channel showerhead (DCSH) 210 are disposed with an insulating ring 220 in between, which allows an AC potential to be applied to the lid 208 relative to the DCSH 310.

The DCSH 210 is disposed between the chamber plasma region 218 and a substrate processing region 224 and allows radicals activated in the plasma present within the chamber plasma region 218 to pass through a plurality of through-holes 226 into the substrate processing region 224. The flow of the radicals (radical flux) is indicated by the solid arrows “A” in FIG. 2A. A substrate 228 is disposed on a substrate support 230 disposed within the substrate processing region 224 and coupled to a bias power source 260. The bias power source 260 can include an RF generator. The DCSH 210 also has one or more hollow volumes 232 which can be filled with a dielectric precursor provided from a precursor source 234. The dielectric precursor passes from the one or more hollow volumes 232 through small holes 236 and into the substrate processing region 224, bypassing the chamber plasma region 218. The flow of the dielectric precursor is indicated by the dotted arrows in FIG. 2A. An exhaust ring 238 is used to uniformly evacuate the substrate processing region 224 by use of an exhaust pump 240. The DCSH 210 may be thicker than the length of the smallest diameter of the through-holes 226. The length of the smallest diameter of the through-holes 226 may be restricted by forming larger diameter portions of through-holes 226 partially through the DCSH 210, to maintain a flow of radical flux from the chamber plasma region 218 into the substrate processing region 224. In some embodiments, the length of the smallest diameter of the through-holes 226 may be the same order of magnitude as the smallest diameter of the through-holes 226 or less.

In some embodiments, a pair of processing chambers (e.g., 1008c-d) in FIG. 1 (referred to as a twin chamber) may be used to deposit a dielectric precursor on the substrate. Each of the processing chambers (e.g., 1008c-d) can have a cross-sectional structure of the processing chamber 200 depicted in FIG. 2A. The flow rates per channel of the DCSH described above correspond to flow rates into each of the chambers (e.g., 1008c-d) via the corresponding DCSH 210.

FIG. 2B is a schematic bottom view of the DCSH 210 according to one embodiment. The DCSH 210 may deliver via through-holes 226 the radical flux and the carrier gas present within the chamber plasma region 218.

In some embodiments, the number of through-holes 226 may be between about 60 and about 2000. Through-holes 226 may have round shapes or a variety of shapes. In some embodiments, the smallest diameter of through-holes 226 may be between about 0.5 mm and about 20 mm or between about 1 mm and about 6 mm. The cross-sectional shape of through-holes 226 may be made conical, cylindrical, or a combination of the two shapes. In some embodiments, a number of small holes 236 may be used to introduce a dielectric precursor into the substrate processing region 224 and may be between about 100 and about 5000 or between about 500 and about 2000. The diameter of the small holes 236 may be between about 0.1 mm and about 2 mm.

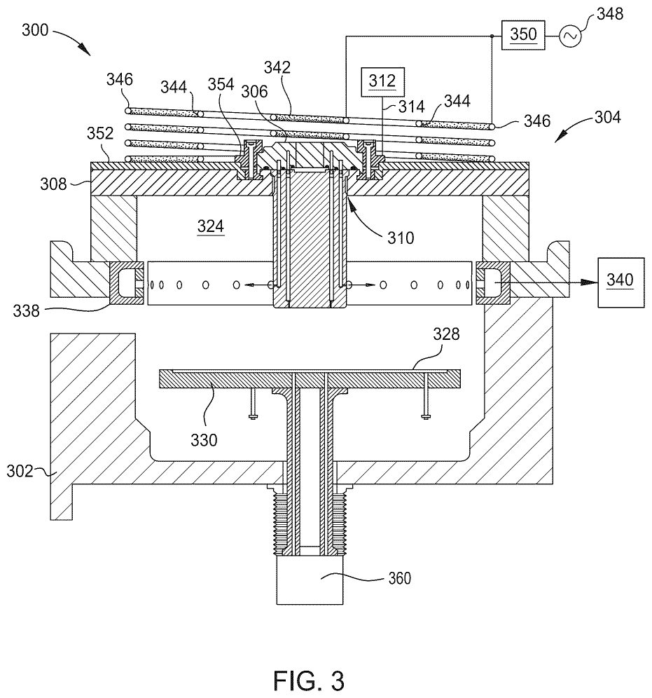

FIG. 3 is a schematic view of a plasma chamber 300 having a chamber body 302 and lid assembly 304, according to some embodiments. The lid assembly 304 includes a gas delivery assembly 306 and a lid 308. The lid 308 has an opening 310 to allow entrance of one or more processing precursor gases. The gas delivery assembly 306 is disposed over the lid 308 through the opening 310. The gas delivery assembly 306 may be connected to a gas source 312 through a gas inlet 314 to supply one or more processing precursor gases into a substrate processing region 324. A substrate 328 is disposed on a substrate support 330 disposed within the substrate processing region 324 and coupled to a bias power source 360. The one or more processing precursor gases may exit the substrate processing region 324 by use of an exhaust ring 338 and an exhaust pump 340.

In the lid assembly 304, inner coils 342, middle coils 344, and outer coils 346 are disposed over the lid 308. The inner coils 342 and the outer coils 346 are coupled to an RF power source 348 through a matching circuit 350. Power applied to the outer coils 346 from the RF power source 348 is inductively coupled through the lid 308 to generate plasma from the processing precursor gases provided from the gas source 312 within the substrate processing region 324. The RF power source 348 can provide current at different frequencies to control the plasma density (i.e., number of ions per cc) in the plasma and thus the density of ion flux (ions/cm²·sec). The bias power source controls a voltage between the substrate 328 and the plasma, and thus controls the energy and directionality of the ions. Thus, both ion flux and ion energy can be independently controlled.

A heater assembly 352 may be disposed over the lid 308. The heater assembly 352 may be secured to the lid 308 by clamping members 354, 356.

The surface of the substrate can be held at a temperature of between about 100° C. and about 400° C. A pressure of the plasma chamber may be maintained between about 5 mTorr and about 500 mTorr.

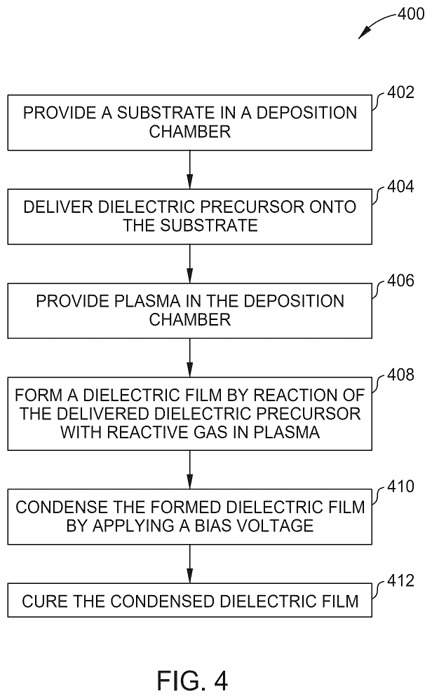

FIG. 4 is a flowchart illustrating a method 400 that is used to form a silicon nitride (SiN)-based dielectric film on a surface of a substrate, according to one embodiment.

At operation 402, a substrate is positioned in a deposition chamber. A substrate, for example, may be a metal substrate, such as aluminum or stainless steel, a semiconductor substrate, such as silicon, silicon-on-insulator (SOI), or gallium arsenide, a glass substrate, or a plastic substrate. A semiconductor substrate may be a patterned substrate at any stage of manufacture/fabrication in the formation of integrated circuits. The patterned substrate may include one or more features, e.g., gaps, trenches, holes, vias, fins, columns, film stacks, layers, films, or other structures disposed on the substrate, that are to be filled with dielectric material. For example, the features can be or include a plurality of fins, where each fin contains a film stack. The film stack can include alternating pairs of layers disposed on one another. In one or more examples, each of the pairs of layers contains silicon-germanium layers and silica layers. Each of the silicon-germanium layers and silica layers can independently be deposited or formed by an epitaxial growth process or an atomic layer deposition (ALD) process.

In one or more embodiments, the features can be or include a plurality of silicon-germanium/silicon (SiGe/Si) fin structures or a plurality of germanium/silicon (Ge/Si) fin structures. In some examples, each of the SiGe layers, the Si layers, or the Ge layers has a thickness of about 5 nm to about 30 nm, such as about 5 nm, about 8 nm, or about 10 nm to about 12 nm, about 15 nm, about 20 nm, about 25 nm, or about 30 nm.

At operation 404, one or more dielectric precursors in a liquid phase and a carrier gas, such as argon (Ar) or helium (He), are flowed into the deposition chamber via a gas delivery device, such as a dual channel showerhead (DCSH), to deliver the dielectric precursor onto a surface of the substrate disposed within the deposition chamber at a flow rate between about 5 sccm to about 5000 sccm per channel of the DSCH, e.g., about 5 sccm to about 250 sccm, about 250 sccm to about 1000 sccm, about 1000 sccm to about 2000 sccm, about 2000 sccm to about 3000 sccm, about 3000 sccm to about 4000 sccm, or about 4000 sccm to about 5000 sccm. The surface of the substrate can be about 40° C. and about 150° C., e.g., about 40° C. to about 60° C., about 60° C. to about 80° C., about 80° C. to about 100° C., about 100° C. to about 120° C., about 120° C. to about 140° C., or about 140° C. to about 150° C. The pressure of the processing chamber can be about 0.5 Torr to about 3 Torr, e.g., about 0.5 Torr to about 1 Torr, about 1 Torr to about 2 Torr, or about 2 Torr to about 3 Torr.

In some embodiments, the dielectric precursor is an organosilicon compound that includes silicon, nitrogen, hydrogen, and chlorine, such as silyl-amine and its derivatives including trisilylamine (TSA) and disilylamine (DSA), an organosilicon compound that includes silicon, nitrogen, hydrogen, and oxygen, or a combination thereof. For example, the organosilicon compound can include an alkylsilane, silazine, siloxane, and/or a combination thereof. As a further example, the organosilicon compound can include a compound having silicon, hydrogen, and/or a combination thereof. In an embodiment, the organosilicon compound can include silane. In various embodiments, the dielectric precursor may be delivered to the surface of the substrate using the carrier gas, e.g., argon, hydrogen, helium, or a combination thereof. In some embodiments, the carrier gas may be delivered at a flow rate of about 250 sccm to about 5000 sccm per channel of the DSCH, e.g., about 250 sccm to about 1000 sccm, about 1000 sccm to about 2000 sccm, about 2000 sccm to about 3000 sccm, about 3000 sccm to about 4000 sccm, or about 4000 sccm to about 5000 sccm.

In some embodiments, a flow ratio of about 1:1 to about 1:200 of dielectric precursor to carrier gas, e.g., about 1:1 to about 1:175, about 1:25 to about 1:166, or about 1:66 to about 1:150. In some embodiments, the dielectric precursor may be delivered to produce an amorphous silica layer formed on and/or over the features.

The amorphous silica layer can have a thickness of about 10 nm to about 1,000 nm, e.g., about 10 nm to about 1,000 nm, about 50 nm to about 800 nm, about 50 nm to about 600 nm, about 50 nm to about 500 nm, about 50 nm to about 400 nm, about 50 nm to about 300 nm, about 50 nm to about 200 nm, about 50 nm to about 100 nm, about 80 nm to about 1,000 nm, about 80 nm to about 800 nm, about 80 nm to about 600 nm, about 80 nm to about 500 nm, about 80 nm to about 400 nm, about 80 nm to about 300 nm, about 80 nm to about 200 nm, about 80 nm to about 100 nm, about 100 nm to about 1,000 nm, about 100 nm to about 800 nm, about 100 nm to about 600 nm, about 100 nm to about 500 nm, about 100 nm to about 400 nm, about 100 nm to about 300 nm, about 100 nm to about 250 nm, or about 100 nm to about 200 nm.

At operation 406, a plasma is generated in a remote plasma source (RPS) outside the deposition chamber and flowed into a substrate processing region of the deposition chamber along with a carrier gas (e.g., Ar, He). The plasma can be generated by the dissociation of a processing precursor gas including molecular oxygen (O₂), ozone (O₃), molecular hydrogen (H₂), a nitrogen-hydrogen compound (e.g., NH₃, N₂H₄) a nitrogen-oxygen compound (e.g., NO, NO₂, N₂O), a hydrogen-oxygen compound (e.g., H₂O, H₂O₂), a nitrogen-hydrogen-oxygen compound (e.g., NH₄OH), a carbon-oxygen compound (e.g., CO, CO₂), or a combination thereof. In the plasma, O*, H*, and/or N*-containing radicals may be activated, such as O*, H*, N*, NH₃*, N₂H₄*, NH₂*, NH*, N*O*, C₃H₆*, C₂H₂*, or a combination thereof.

At operation 408, one or more radicals (also referred to as reactive gas) in the substrate processing region react with the delivered dielectric precursor to form a silicon nitride (SiN)-based dielectric film. The composition of the formed silicon nitrogen (Si—N)-based dielectric film can be adjusted by changing the composition of the reactive gas in the radical flux. To form a nitrogen-containing film, such as SiON, SiCON, and SiN films, the reactive gas may be, for example, ammonia (NH₃), hydrogen (H₂), hydrazine (N₂H₄), nitrogen dioxide (NO₂), or nitrogen (N₂). When the reactive gas in the substrate processing region reacts with the delivered dielectric precursor, Si—H and N—H bonds (weaker bonds) are partially broken and replaced by Si—N, Si—NH, and/or Si—NH₂ bonds (stronger bonds) to form a silicon nitride (SiN)-dielectric film.

In some embodiments, the ion energy of the one or more radicals may be about 10 eV to about 200 eV, e.g., about 10 eV to about 40 eV, about 40 eV to about 60 eV, or about 60 eV to about 70 eV. In some embodiments, the dosage value of the one or more radicals may be about 1×10¹⁸ ion/cm² to about 6×10²⁰ ion/cm² during the plasma treatment, e.g., about 1×10¹⁸ ion/cm² to about 2×10²⁰ ion/cm², about 2×10²⁰ ion/cm² to about 3×10²⁰ ion/cm², about 3×10²⁰ ion/cm² to about 4×10²⁰ ion/cm², about 4×10²⁰ ion/cm² to about 5×10²⁰ ion/cm², or about 5×10²⁰ ion/cm² to about 6×10²⁰ ion/cm².

In some embodiments, the radicals activated in the RPS are flowed into the processing chamber (referred to as “radical flux”) at a flow rate between about 1 sccm and about 10000 sccm. The composition of the formed SiN-based dielectric film can be adjusted by changing the composition of the reactive gas in the radical flux. To form a nitrogen-containing film, such as SiON, SiCON, and SiN films, the reactive gas may be, for example, ammonia (NH₃), hydrogen (H₂), hydrazine (N₂H₄), nitrogen dioxide (NO₂), or nitrogen (N₂). Without being bound by theory, when the reactive gas in the substrate processing region reacts with the delivered dielectric precursor, Si—H and N—H bonds (weaker bonds) are partially broken and replaced by Si—N, Si—NH, and/or Si—NH₂ bonds (stronger bonds) to form a SiN-dielectric film.

At operation 410, the silicon nitride (SiN)-based dielectric film can be condensed by applying a bias plasma containing light ions (e.g., ionized species having small atomic numbers in the periodic table), such as argon (e.g., Ar), nitrogen (e.g., N₂), oxygen (e.g., O₂), hydrogen (e.g., H₂), tetrafluoromethane (CF₄), nitrogen trifluoride (NF₃), and/or carbon (e.g., C*), to the formed silicon nitride (SiN)-based dielectric film. The bias plasma, which can be generated by two or more power sources (e.g., an RF power source), can control the density of ion flux (also referred to as ion dose). The bias plasma can be generated via inductive coils and a DC bias, to control ion bombardment energy. Without being bound by theory, by applying the bias plasma after deposition of the dielectric precursor, the silicon nitride (SiN)-based dielectric film can be condensed by causing Si—H and Ni—H bonds to break, thereby forming a greater number of Si—N—Si bonds in the dielectric film and reducing the dielectric constant of the dielectric film.

The RF source can have a power of about 50 watts (W) to about 300 W, e.g., about 50 W to about 280 W, about 55 W to about 250 W, about 55 W to about 150 W, or about 55 W to about 100 W, when operating at a frequency of about 400 kHz to about 30 MHZ, e.g., about 4000 kHz to about 1 MHZ, about 1 MHz to about 10 MHz, about 10 MHz to about 20 MHz, about 22 MHz to about 24 MHZ, about 24 MHz to about 26 MHz, about 26 MHz to about 28 MHz, or about 28 MHz to about 30 MHz.

The DC bias can have a voltage of about 0.1 kV to about 10 kV, about 0.1 kV to about 8 kV, about 0.1 kV to about 7 kV, about 0.1 kV to about 6 kV, about 0.1 kV to about 5 kV, about 0.1 kV to about 4 kV, about 0.1 kV to about 2 kV, about 0.1 kV to about 1 kV, about 0.1 kV to about 0.5 kV, about 1 kV to about 10 kV, about 1 kV to about 8 kV, about 1 kV to about 7 kV, about 1 kV to about 6 kV, about 1 kV to about 5 kV, about 1 kV to about 4 kV, about 3 kV to about 10 kV, about 3 kV to about 8 kV, about 3 kV to about 7 kV, about 3 kV to about 6 kV, or about 3 kV to about 5 kV.

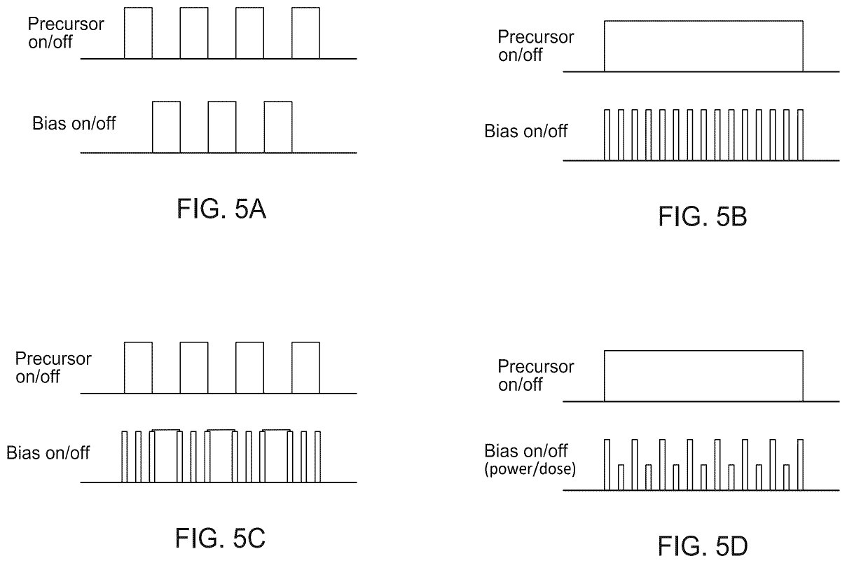

In some embodiments, the bias plasma can be applied according to a first treatment process. The first treatment process including applying the bias plasma after the deposition of the dielectric precursor in a sequential manner, as shown in FIG. 5A. For example, a first deposition of the dielectric precursor may occur, followed by a first bias plasma. In some embodiments, the first deposition and first bias plasma may be iteratively cycled to provide a first deposition, first bias plasma, second deposition, second bias plasma, third deposition, third bias plasma, and so on. The iterative cycling may occur for about 2 cycles to about 100 cycles, e.g., about 2 cycles to about 95 cycles, about 5 cycles to about 80 cycles, about 10 cycles to about 60 cycles, about 20 cycles to about 50 cycles, or about 30 cycles to about 40 cycles.

In some embodiments, the bias plasma can be applied according to a second treatment process. The second treatment process can include applying the bias plasma by pulsing the bias plasma during the deposition of the dielectric precursor, as shown in FIG. 5B. The deposition of the dielectric precursor can occur continuously, in which the bias plasma containing light ions may be pulsed during the deposition. Each pulse can occur for about 0.5 s to about 100 s, e.g., about 0.5 s to about 90 s, about 0.5 s to about 50 s, about 1 s to about 30 s, or about 5 s to about 10 s, and the pulses can be spaced by about 0.1 s to about 100 s, e.g., about 0.1 s to about 90 s, about 0.5 s to about 50 s, about 1 s to about 30 s, or about 5 s to about 10 s.

In some embodiments, the bias plasma can be applied according to a third treatment process. The third treatment process can include applying the bias plasma in a sequential manner after depositing the dielectric precursor, and pulsing the bias plasma during the deposition of the dielectric precursor, as shown in FIG. 5C. Each pulse can occur for about 0.5 s to about 100 s, e.g., about 0.5 s to about 90 s, about 0.5 s to about 50 s, about 1 s to about 30 s, or about 5 s to about 10 s, and the pulses can be spaced by about 0.1 s to about 100 s, e.g., about 0.1 s to about 90 s, about 0.5 s to about 50 s, about 1 s to about 30 s, or about 5 s to about 10 s.

In some embodiments, the bias plasma can be applied according to a fourth treatment process. The fourth treatment process can include applying a first pulse of a bias plasma having a first frequency, and applying a second pulse of a bias plasma having a second frequency during the deposition of the dielectric precursor, as shown in FIG. 5D. In some embodiments, the first pulse can occur for about 0.5 s to about 100 s, e.g., about 0.5 s to about 90 s, about 0.5 s to about 50 s, about 1 s to about 30 s, or about 5 s to about 10 s. In some embodiments, the first frequency can include a frequency of about 400 kHz to about 30 MHz, e.g., about 4000 kHz to about 1 MHZ, about 1 MHz to about 10 MHz, about 10 MHz to about 20 MHz, about 22 MHz to about 24 MHZ, about 24 MHZ to about 26 MHz, about 26 MHz to about 28 MHz, or about 28 MHz to about 30 MHz.

In some embodiments, the second pulse may be applied after the first pulse and a preconfigured period of time of about 0.1 s to about 100 s, e.g., about 0.1 s to about 90 s, about 0.5 s to about 50 s, about 1 s to about 30 s, or about 5 s to about 10 s. In some embodiments, the second pulse can occur for about 0.5 s to about 100 s, e.g., about 0.5 s to about 90 s, about 0.5 s to about 50 s, about 1 s to about 30 s, or about 5 s to about 10 s. In some embodiments, the second frequency can include a frequency of about 400 kHz to about 30 MHz, e.g., about 4000 kHz to about 1 MHz, about 1 MHz to about 10 MHz, about 10 MHz to about 20 MHz, about 22 MHz to about 24 MHZ, about 24 MHz to about 26 MHZ, about 26 MHz to about 28 MHz, or about 28 MHz to about 30 MHz. In some embodiments, the first pulse and the second pulse can be alternated, e.g., sequentially pulsed.

At operation 412, the formed silicon nitride (SiN)-based dielectric film is cured using a curing process. The curing process can include a thermal curing process and/or an ultra-violet curing process, e.g., 150 nm to about 400 nm, (UV curing process). In some embodiments, the thermal curing process and/or UV curing process can include flowing a carrier gas, e.g., argon, helium, nitrogen, ammonium, oxygen, ozone, peroxide, and/or hydrogen into the chamber while heating the formed silicon-nitride (SiN)-based dielectric film to a temperature of about 100° C. to about 500° C., e.g., about 150° C. to about 500° C., about 200° C. to about 450° C., about 250° C. to about 400° C., or about 300° C. to about 350° C. Without being bound by theory, a curing temperature of about 100° C. to about 500° C. can reduce residual Si—OH bonding remaining in the formed silicon nitride (SiN)-based dielectric film, thereby improving electrical properties, e.g., leakage current and/or breakdown voltage, of the film. In some embodiments, at operation 412, the formed silicon nitride (SiN)-based dielectric film can be washed using a wet treatment process. The wet treatment process can include washing the formed silicon nitride (SiN)-based dielectric film with peroxide and/or water to remove residual precursors and/or contaminants from the film.

In some embodiments, the curing the dielectric precursor, e.g., operation 412, can be performed in a chamber different from the deposition chamber in which the delivery and reaction of the dielectric precursor with the reactive gas (blocks 404-410) are performed. In some embodiments, the curing the dielectric precursor, e.g., operation 412, can performed in the same chamber as the deposition chamber in which the delivery and reaction of the dielectric precursor with the reactive gas (blocks 404-410) are performed. In general, the set of operations (e.g. blocks 404-410) may be repeated for multiple cycles to form an overall thicker film.

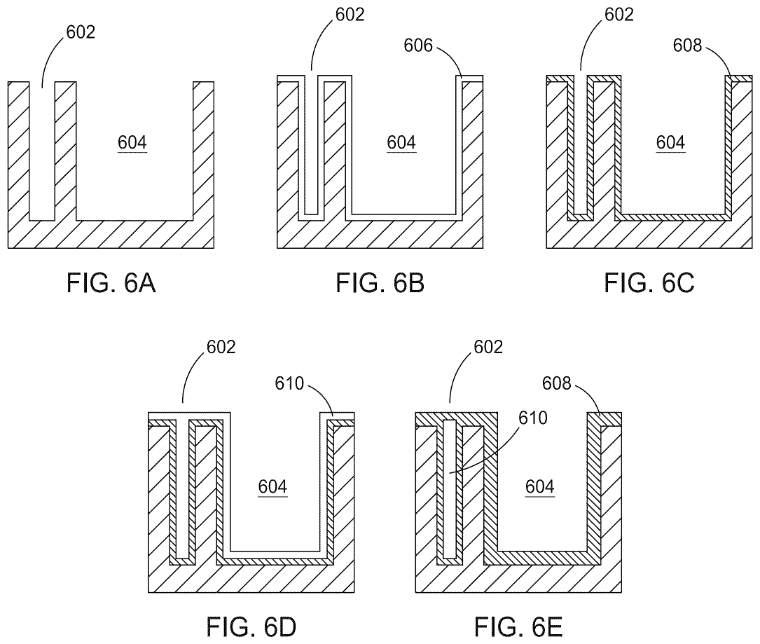

Now referring to FIGS. 6A-6E, a diagrammatic representation of a first treatment process is shown. In some embodiments, the substrate can include a plurality of features, e.g., a narrow trench 602 and a wide trench 604, as shown in FIG. 6A. A first deposition of the dielectric precursor can be performed to form a first layer 606 of a silicon nitride (SiN)-based dielectric film over the narrow trench 602 and the wide trench 604, as shown in FIG. 6B. A first bias plasma can be applied to the substrate to condense the first layer 606 to form a condensed film 608, thereby increasing a density of the film, and reducing a concentration of Si—H and/or N—H bonds in the film, as shown in FIG. 6C. The first bias plasma may condense a portion of the first layer 606 in the narrow trench 602, as shown in FIG. 6C. A second deposition process may be performed to deposit a second layer 610 of a silicon nitride (SiN)-based dielectric film. In some embodiments, the first deposition process followed by the condensation and second deposition process can be repeated to fill the narrow trench 602, as shown in FIG. 6D. In some embodiments, a second bias plasma can be applied to the substrate to condense the second layer 610 to form the condensed film 608. The condensed film 608 may form over the narrow trench 602, such that the narrow trench retains the second layer 610 in a gap of the narrow trench, while coated with the condensed film 608, as shown in FIG. 6E.

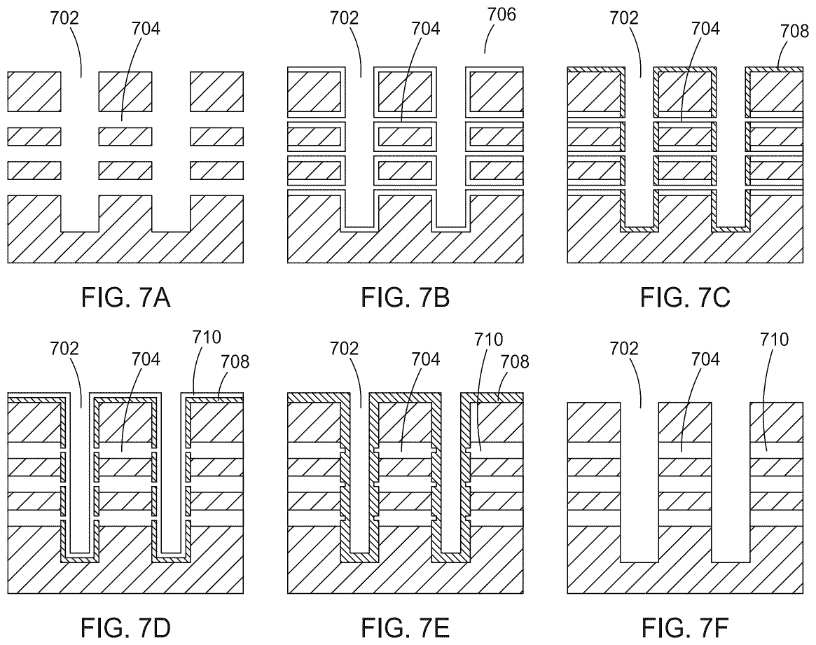

Now referring to FIGS. 7A-7F, a diagrammatic representation of a first treatment process is shown. In some embodiments, the substrate can include a plurality of features, e.g., a vertical trench 702 and a horizontal trench 704, as shown in FIG. 7A. A first deposition of the dielectric precursor can be performed to form a first layer 706 of a silicon nitride (SiN)-based dielectric film over the vertical trench 702 and a horizontal trench 704, as shown in FIG. 7B. A first bias plasma can be applied to the substrate to condense the first layer 706 disposed over the vertical trench 702 to form a condensed film 708, as shown in FIG. 7C. A second deposition process may be performed to deposit a second layer 710 of a silicon nitride (SiN)-based dielectric film, as shown in FIG. 7D. In some embodiments, the first deposition process followed by the condensation and second deposition process can be repeated to fill the horizontal trench 704, as shown in FIG. 7D. In some embodiments, a second bias plasma can be applied to the substrate to condense the second layer 710 to form the condensed film 708. The condensed film 708 may form over the vertical trench 702, such that the horizontal trench 704 retains the second layer 710 in a gap of the narrow trench, while coated with the condensed film 708, as shown in FIG. 7E. The condensed film 708 can be washed to remove the condensed film 708 from the vertical trench 702, allowing the second layer 710 to remain in the horizontal trench 704, as shown in FIG. 7F.

### EXAMPLES

A flowable film was produced according to method 400, as described in the present application, as shown in FIG. 8. The carbon to oxygen ratio of dielectric precursors when forming a flowable film was varied to produce a V_{bd} of about 1.5 to about 3.0 and a dielectric constant (k), e.g., less than 3. When the flowable film was treated according to a first treatment process (Example 1) or a second treatment process (Example 2), as described above, in which the V_{bd} and k was monitored during the treatment. Example 1 resulted in a V_{bd} that remained above 4.5 MV/cm, and the k remained below 3.4, when treated with up to 800 W. Example 1 resulted in a V_{bd} that remained above 4.5 MV/cm, and the k remained below 3.4, when using a duty cycle of about 0.01% to 60% on 2 MHz and 1% to 99% on 13 MHz, thereby reducing or preventing current leakage when the device transistor switch is on.

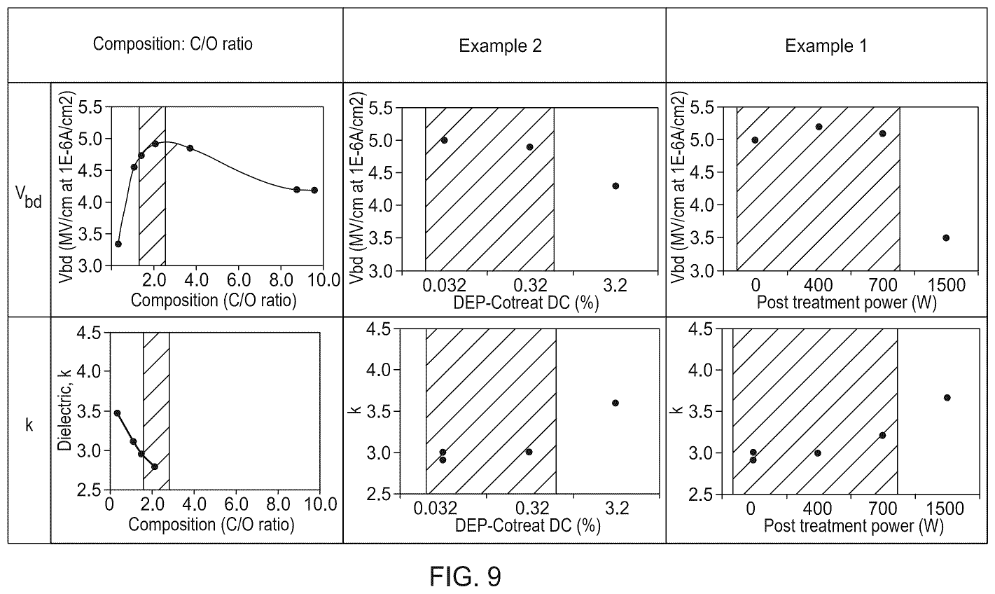

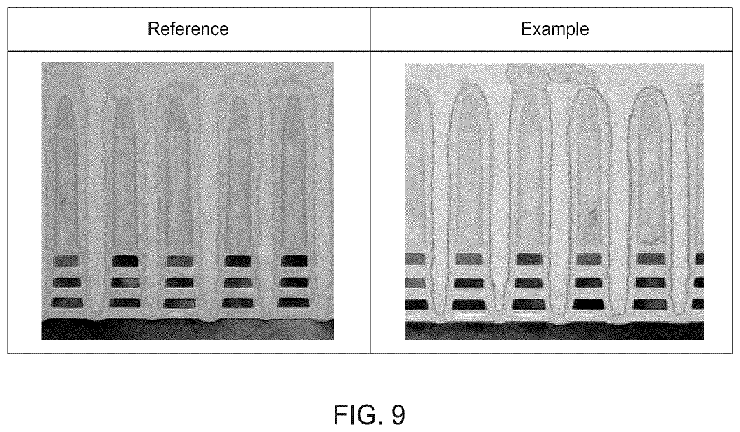

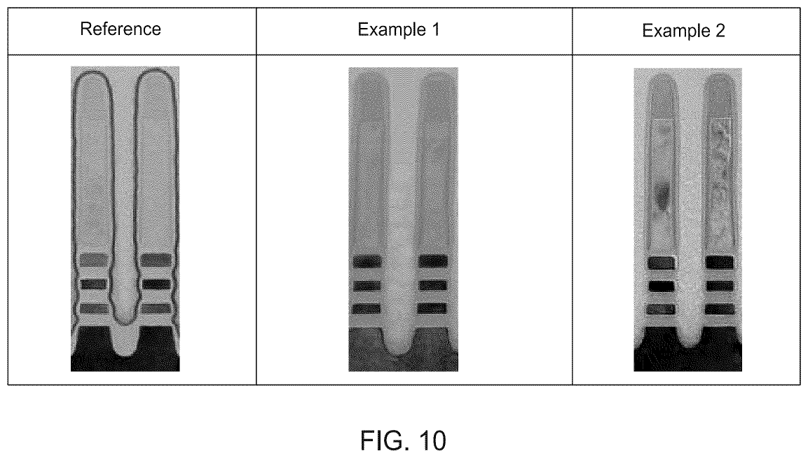

A flowable film produced according to method 400 (Example) was compared to a flowable film that was not condensed with the bias voltage (Reference), as shown in FIG. 9. The Reference had a top and side thickness of 12.7 nm and 5.5 nm, respectively, while the Example had a top and side thickness of about 4.1 nm and 4.5 nm, respectively. The Reference had a step coverage (side/top) of about 45%, while the Example had a step coverage (side/top) of about 109%. The Reference had a step coverage (sider/sideB) of about 66%, while the Example had a step coverage (sider/sideB) of about 74%.

A reference film not condensed with a bias voltage (Reference) was compared to a flowable film produced according to method 400 (Example 1) and a flowable film produced according to method 400 followed by a hydrogen etch (Example 2), as shown in FIG. 10. The Reference, Example 1, and Example 2 each provided a seam free gap fill material. The Reference provided a conformality (B/T), target 1.0 of 6.7, while Example 1 provided a conformality (B/T), target 1.0 of 1.7, and Example 2 provided a conformality (B/T), target 1.0 of 1.9. The Reference had a step coverage (sideB/sider) of about 0.7, and the Example 1 and Example 2 had a step coverage (sideB/sider) of about 0.7 and 0.9, respectively. The Reference had a thickness of about 2.8 nm (top) 3.0 nm (side), and 19.0 nm (bottom). Example 1 had a thickness of about 5.4 nm (top) 5.0 nm (side), and 9.2 nm (bottom). Example 2 had a thickness of about 4.0 nm (top) 3.8 nm (side), and 8.2 nm (bottom).

In summation, the present disclosure provides low temperature deposition processes that enable uniform deposition and bottom up fill in narrow opening critical dimensions, reducing the formation of Si—H and/or N—H bonds. Moreover, the present disclosure can reduce the dielectric constant due to an increase in porosity and/or due to the formation of a non-polarization structure by providing Si—C based precursors with O, N incorporation. The techniques disclosed herein can improve the density of deposited films due to ion bombardment on the substrate support, thereby improving hardness and reducing dry/wet etch rate of the film. Additionally, the present disclosure can provide a low thermal cure process, e.g., less than 500° C., thereby reducing Si—OH bonding and improving electrical properties, e.g., leakage current and/or breakdown voltage. Embodiments described herein also provide a tunable deposition process that can fill a gap of a structure, e.g., a vertical trench and/or a horizontal trench, in a gate all round transistor, e.g., 3D NAND, 3D DRAM and CFET device.

While the foregoing is directed to specific embodiments, other and further embodiments may be devised without departing from the basic scope thereof, and the scope thereof is determined by the claims that follow.

1. A method of post-treating a silicon nitride (SiN)-based dielectric film formed on a surface of a substrate, comprising:
positioning a substrate in a processing chamber;
supplying a dielectric precursor to the processing chamber;
providing a plasma to the processing chamber, wherein the dielectric precursor reacts with a reactive gas in the plasma to form a silicon nitride (SiN)-based dielectric film on the substrate;
applying a bias plasma to the silicon nitride (SiN)-based dielectric film to form a condensed silicon nitride (SiN)-based dielectric film; and
curing the condensed silicon nitride (SiN)-based dielectric film.

2. The method of claim 1, wherein applying the bias plasma comprises pulsing the bias plasma.

3. The method of claim 2, wherein each pulse of the bias plasma occurs for about 0.5 s to about 100 s.

4. The method of claim 3, wherein a first pulse of the bias plasma is spaced from a second pulse of the bias plasma by about 0.1 s to about 100 s.

5. The method of claim 1, wherein the bias plasma comprises a dual frequency bias plasma comprising a first frequency and a second frequency.

6. The method of claim 5, wherein the first frequency is about 400 kHz to about 30 MHz and the second frequency is about 400 KHz to about 30 MHz, wherein the first frequency and the second frequency are different.

7. The method of claim 1, wherein the condensed dielectric film comprises a dielectric value of about 2.5 to about 3.5.

8. The method of claim 1, wherein the condensed dielectric film comprises a breakdown voltage (V_{bd}) of about 4.5 MV/cm to about 5.5 MV/cm.

9. The method according to claim 1, wherein the dielectric precursor is an organosilicon compound comprising at least one of silicon, nitrogen, hydrogen, chlorine, or oxygen.

10. The method according to claim 1, wherein the reactive gas comprises one or more of oxygen (O₂), ozone (O₃), water (H₂O), ammonia (NH₃), hydrazine (N₂H₄), nitrogen dioxide (NO₂), nitrogen (N₂), tetrafluoromethane (CF₄), or nitrogen trifluoride (NF₃).

11. A method of post-treating a silicon nitride (SiN)-based dielectric film formed on a surface of a substrate, comprising:
positioning a substrate in a processing chamber;
forming a condensed silicon nitride (SiN)-based dielectric film, the forming comprising:
supplying a dielectric precursor to the processing chamber;
providing a plasma to the processing chamber, wherein the dielectric precursor reacts with a reactive gas in the plasma to form a silicon nitride (SiN)-based dielectric film; and
applying a bias plasma concurrently to form the condensed silicon nitride (SiN)-based dielectric film; and
curing the condensed silicon nitride (SiN)-based dielectric film.

12. The method of claim 11, wherein applying the bias plasma comprises pulsing the bias plasma.

13. The method of claim 11, wherein each pulse of the bias plasma occurs for about 0.5 s to about 100 s.

14. The method of claim 13, wherein a first pulse of the bias plasma is spaced from a second pulse of the bias plasma by about 0.1 s to about 100 s.

15. The method of claim 11, wherein the bias plasma comprises a dual frequency bias plasma comprising a first frequency and a second frequency.

16. The method of claim 15, wherein the first frequency is about 400 KHz to about 30 MHz and the second frequency is about 400 kHz to about 30 MHz, wherein the first frequency and the second frequency are different.

17. The method of claim 11, wherein the condensed dielectric film comprises a dielectric value of about 2.5 to about 3.5.

18. The method of claim 11, wherein the condensed dielectric film comprises a V_{bd} of about 4.5 MV/cm to about 5.5 MV/cm.

19. The method according to claim 11, wherein the dielectric precursor is an organosilicon compound comprising at least a silicon, nitrogen, hydrogen, chlorine or oxygen.

20. The method according to claim 11, wherein the reactive gas comprises one or more of oxygen (O₂), ozone (O₃), water (H₂O), ammonia (NH₃), hydrazine (N₂H₄), nitrogen dioxide (NO₂), nitrogen (N₂), tetrafluoromethane (CF₄), or nitrogen trifluoride (NF₃).
